(19) United States
(12) Patent Application Publication
(10) Pub. No.: US 2026/0113032 A1
(43) Pub. Date: Apr. 23, 2026

(54) POWER SEMICONDUCTOR DEVICE

(71) Applicant: Mitsubishi Electric Corporation, Tokyo (JP)

(72) Inventors: Ryo NAMIMATSU, Tokyo (JP); Toru ICHIMURA, Tokyo (JP); Toshiya TADAKUMA, Tokyo (JP)

(73) Assignee: Mitsubishi Electric Corporation, Tokyo (JP)

(21) Appl. No.: 19/306,547

(22) Filed: Aug. 21, 2025

(30) Foreign Application Priority Data
Oct. 18, 2024 (JP) 2024-182935

(51) Int. Cl. H03K 17/687

(52) U.S. Cl. CPC H03K 17/6877; H03K 2217/0027

(57) ABSTRACT

A power semiconductor device includes at least one power semiconductor element having an emitter terminal through which an emitter current flows and a sense terminal through which a sense current proportional to the emitter current flows, and a first current mirror circuit. The sense terminal is connected to an output terminal of the first current mirror circuit, and an input terminal of the first current mirror circuit is connected to a first current source.

### BACKGROUND

### Technical Field

The present disclosure relates to a power semiconductor device.

### Description of the Background Art

In a power semiconductor device using a power semiconductor element such as an insulated gate bipolar transistor (IGBT), a sense terminal is provided separately from a main terminal for the purpose of estimating the main current of the power semiconductor element. In the IGBT, the main terminal is an emitter terminal. The main electrode of the power semiconductor element is divided between the main terminal and the sense terminal. According to the area ratio of the divided main electrodes, a sense current, divided from a main current, flows through the sense terminal. The main current is estimated from the measurement value of the small sense current. As a conventional technique, there is a semiconductor device disclosed in Japanese Patent Application Laid-Open No. 2015-089050.

In order to estimate the main current with high accuracy, it is ideal that the main current and the sense current be in a proportional relationship. However, a potential difference occurs between a main voltage and a sense voltage due to a resistor connected between the sense terminal and the main terminal, and thus there is a problem that the proportional relationship between them collapses and the estimation accuracy of the main current deteriorates.

### SUMMARY

An object of the present disclosure is to estimate the main current at a power semiconductor element with high accuracy.

A power semiconductor device of the present disclosure includes at least one power semiconductor element and a first current mirror circuit. The at least one power semiconductor element includes a main terminal through which a main current flows and a sense terminal through which a sense current proportional to the main current flows. The sense terminal is connected to an output terminal of the first current mirror circuit. An input terminal of the first current mirror circuit is connected to a first current source.

According to the power semiconductor device of the present disclosure, a potential difference between the main terminal and the sense terminal of the power semiconductor element is reduced, so that a current division ratio between the main current and the sense current is stabilized. As a result, the main current can be estimated from the sense current with high accuracy.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a circuit diagram of a power semiconductor device of a first preferred embodiment;

FIG. 2 is a graph illustrating an operation of the power semiconductor device of the first preferred embodiment;

FIG. 3 is a graph illustrating a voltage and a current at each part of the power semiconductor device of the first preferred embodiment;

FIG. 4 is a circuit diagram of a power semiconductor device of a second preferred embodiment;

FIG. 5 is a circuit diagram of a power semiconductor device of a third preferred embodiment;

FIG. 6 is a circuit diagram of a power semiconductor device of a fourth preferred embodiment;

FIG. 7 is a circuit diagram of a power semiconductor device of a fifth preferred embodiment;

FIG. 8 is a graph illustrating an operation of the power semiconductor device of the fifth preferred embodiment;

FIG. 9 is a circuit diagram of a power semiconductor device of a sixth preferred embodiment;

FIG. 10 is a graph illustrating an operation of the power semiconductor device of the sixth preferred embodiment;

FIG. 11 is a circuit diagram of a power semiconductor device of a seventh preferred embodiment;

FIG. 12 is a circuit diagram of a power semiconductor device of an eighth preferred embodiment;

FIG. 13 is a graph illustrating an operation of the power semiconductor device of the eighth preferred embodiment;

FIG. 14 is a circuit diagram of a power semiconductor device of a ninth preferred embodiment;

FIG. 15 is a circuit diagram of a power semiconductor device of a tenth preferred embodiment;

FIG. 16 is a graph illustrating an operation of the power semiconductor device of the tenth preferred embodiment;

FIG. 17 is a circuit diagram of a power semiconductor device of an eleventh preferred embodiment;

FIG. 18 is a circuit diagram of a power semiconductor device of a twelfth preferred embodiment;

FIG. 19 is a circuit diagram of a power semiconductor device of a thirteenth preferred embodiment;

FIG. 20 is circuit diagrams of a power semiconductor device of a fourteenth preferred embodiment;

FIG. 21 are graphs illustrating an operation of the power semiconductor device of the fourteenth preferred embodiment;

FIG. 22 is a circuit diagram of a power semiconductor device of a fifteenth preferred embodiment;

FIG. 23 is a circuit diagram of a power semiconductor device of a sixteenth preferred embodiment;

FIG. 24 is a circuit diagram of a power semiconductor device of a seventeenth preferred embodiment;

FIG. 25 is a circuit diagram of a power semiconductor device of a conventional technology; and

FIG. 26 is a graph illustrating an ideal sense current and an actual sense current at the power semiconductor device of the conventional technology.

### DESCRIPTION OF THE PREFERRED EMBODIMENTS

### A. Conventional Technology

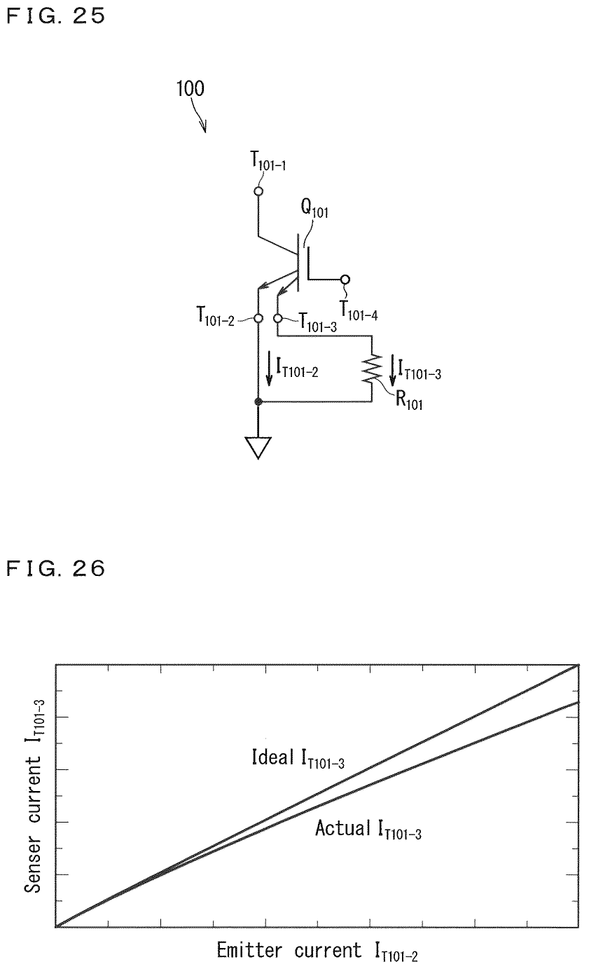

FIG. 25 is a circuit diagram of a power semiconductor device 100 of the conventional technology.

The power semiconductor device 100 includes a power semiconductor element Q₁₀₁. In the example of FIG. 25, the power semiconductor element Q₁₀₁ is an IGBT. The power semiconductor element Q₁₀₁ includes a collector terminal T₁₀₁₋₁ as an output terminal, an emitter terminal T₁₀₁₋₂ as a main terminal, a sense terminal T₁₀₁₋₃, and a gate terminal T₁₀₁₋₄ as a control terminal. An emitter electrode, which is a main electrode of the power semiconductor element Q₁₀₁, is divided into a portion to be connected to the emitter terminal T₁₀₁₋₂ and a portion to be connected to the sense terminal T₁₀₁₋₃. A sense current I_{T101-3}, divided according to the area ratio of the emitter electrode, flows to the sense terminal T₁₀₁₋₃. The sense current I_{T101-3} is smaller than an emitter current I_{T101-2} that is a main current. By reading this small sense current I_{T101-3}, it is possible to estimate the emitter current I_{T101-2} without directly reading it.

A resistor R₁₀₁ is connected to the sense terminal T₁₀₁₋₃. The sense current I_{T101-3} is calculated by a potential difference between the sense terminal T₁₀₁₋₃ and the emitter terminal T₁₀₁₋₂. That is, the sense current I_{T101-3} is calculated by (I_{T101-3})=(voltage drop across the resistor R₁₀₁)/(resistance value of the resistor R₁₀₁).

As described above, when the resistor R₁₀₁ is connected between the sense terminal T₁₀₁₋₃ and the emitter terminal T₁₀₁₋₂, the sense current I_{T101-3} can be converted into a voltage and measured. However, the voltage drop across the resistor R₁₀₁ is proportional to the sense current I_{T101-3}, and thus it has been necessary to accurately set the detection threshold of a comparator with respect to the value of the sense current I_{T101-3} to be detected.

In addition, there has been a technical problem that if the detection voltage at the comparator is low, erroneous detection increases due to voltage fluctuation, current fluctuation, or external noise of the power semiconductor element Q₁₀₁ and a peripheral circuit.

Furthermore, the impedance of a node that detects the sense terminal T₁₀₁₋₃ of the power semiconductor element Q₁₀₁ depends on the resistance value of the resistor R₁₀₁ connected to the sense terminal T₁₀₁₋₃. When the resistance value of the resistor R₁₀₁ is lowered, the impedance is lowered, and thus the voltage, converted from the incoming noise current, can be suppressed to a low level. However, the detection threshold based on the GND potential is lowered, which causes an adverse effect of decreasing a noise margin with respect to a noise voltage.

It is ideal that the sense current I_{T101-3} be maintained to be proportional to the emitter current I_{T101-2}. However, a potential difference occurs between the emitter voltage and the sense voltage due to the resistor R₁₀₁, and thus the actual sense current I_{T101-3} deviates from the ideal sense current I_{T101-3}, as illustrated in FIG. 26.

There is also a problem that when the resistance value of the resistor R₁₀₁ is increased as a countermeasure against the noise voltage, that is, when a large potential difference is applied between the emitter voltage and the sense voltage, the imbalance in the current division ratio between the emitter current I_{T101-2} and the sense current I_{T101-3} increases, which deteriorates current detection accuracy.

### B. First Preferred Embodiment

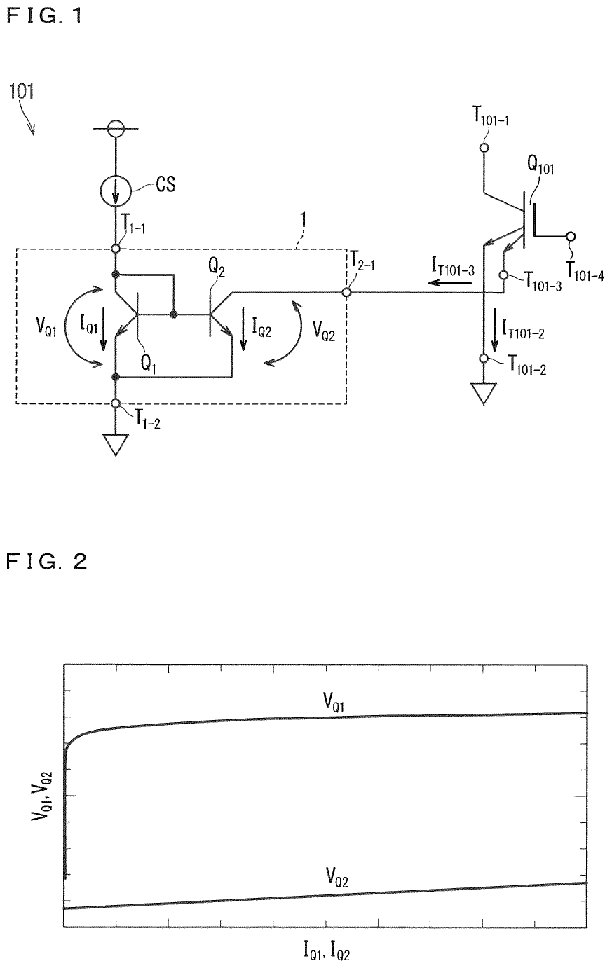

FIG. 1 is a circuit diagram of a power semiconductor device 101 of a first preferred embodiment. The power semiconductor device 101 includes a power semiconductor element Q₁₀₁, a first current mirror circuit 1 connected to a sense terminal T₁₀₁₋₃ of the power semiconductor element Q₁₀₁, and a first current source CS that supplies a current to an input terminal T₁₋₁ of the first current mirror circuit 1.

In the power semiconductor device 100 of the conventional technology, the resistor R₁₀₁ is connected to the sense terminal T₁₀₁₋₃, but in the power semiconductor device 101 of the first preferred embodiment, an output terminal T₂₋₁ of the first current mirror circuit 1 is connected to the sense terminal T₁₀₁₋₃. The sense terminal T₁₀₁₋₃ and the output terminal T₂₋₁ may be connected by a wire containing at least one material of Al, Au, and Ag. In addition, the power semiconductor device 101 may be sealed with a sealing material.

The first current mirror circuit 1 includes a first transistor Q₁ and a second transistor Q₂. In the example of FIG. 1, both the first transistor Q₁ and the second transistor Q₂ are bipolar transistors. The first transistor Q₁ is a reference transistor, while the second transistor Q₂ is a mirror transistor. A collector terminal, which is the output terminal of the first transistor Q₁, and a base terminal, which is the control terminal, are connected to the input terminal T₁₋₁ of the first current mirror circuit 1. A collector terminal, which is the output terminal of the second transistor Q₂, is connected to the output terminal T₂₋₁ of the first current mirror circuit 1. Emitter terminals, which are the main terminals of the first transistor Q₁ and the second transistor Q₂, are connected to an emitter terminal T₁₋₂, which is the main terminal of the first current mirror circuit 1.

FIG. 2 illustrates relationships between collector-emitter currents I_{Q1}, I_{Q2} and collector-emitter voltages V_{Q1}, V_{Q2} at the first transistor Q₁ and the second transistor Q₂ in the first current mirror circuit 1 of the power semiconductor device 101.

According to the configuration of the power semiconductor device 101 described above, the potential difference between an emitter terminal T₁₀₁₋₂ and the sense terminal T₁₀₁₋₃ of the power semiconductor element Q₁₀₁ is as small as possible and becomes a constant value, so that a current division ratio between an emitter current I_{T101-2} and a sense current I_{T101-3} is stabilized. As a result, the emitter current I_{T101-2} can be accurately detected from the sense current I_{T101-3}.

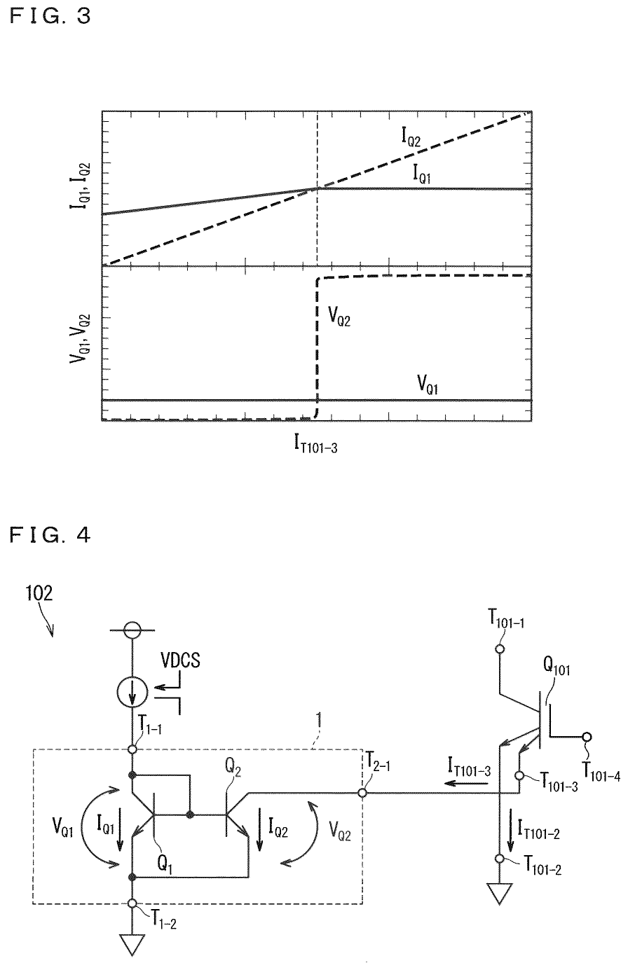

As illustrated in FIG. 1, the first current source CS that supplies a current to the input terminal T₁₋₁ of the first current mirror circuit 1 may be a constant current source. In this case, the voltage and current at each part of the power semiconductor device 101 are as illustrated in FIG. 3, and the following effects can be obtained.

The sense current I_{T101-3} is equal to the collector-emitter current I_{Q2} at the second transistor Q₂.

When (sense current I_{T101-3})<(collector-emitter current I_{Q1} at first transistor Q₁), a base current is excessively supplied to the second transistor Q₂, and the collector-emitter voltage V_{Q2} at the second transistor Q₂ is kept lower than the collector-emitter voltage V_{Q1} at the first transistor Q₁. That is, a voltage V_{GS} between the gate terminal T₁₀₁₋₄ and the sense terminal T₁₀₁₋₃ of the power semiconductor element Q₁₀₁ is not greatly different from a voltage V_{GE} between the gate terminal T₁₀₁₋₄ and the emitter terminal T₁₀₁₋₂, which allows V_{GS}≈V_{GE} to hold. Therefore, the proportional relationship between the emitter current I_{T101-2} and the sense current I_{T101-3} at the power semiconductor element Q₁₀₁ is maintained with high accuracy.

When (sense current I_{T101-3})>(collector-emitter current I_{Q1} at first transistor Q₁), the second transistor Q₂ cannot sink current, and thus the collector-emitter voltage V_{Q2} at the second transistor Q₂ becomes a high value. That is, when the sense current I_{T101-3} exceeds the collector-emitter current I_{Q1} at the first transistor Q₁, a potential V₁₀₁₋₃ of the sense terminal T₁₀₁₋₃ greatly changes. Therefore, by detecting the potential of the sense terminal T₁₀₁₋₃, it is possible to clearly determine overcurrent or short-circuit current and easily create a circuit for protecting the power semiconductor element Q₁₀₁ and the power semiconductor device 101.

### C. Second Preferred Embodiment

FIG. 4 is a circuit diagram illustrating a configuration of a power semiconductor device 102 of a second preferred embodiment. The power semiconductor device 102 is different from the power semiconductor device 101 of the first preferred embodiment only in that the first current source CS that supplies a current to the input terminal T₁₋₁ of the first current mirror circuit 1 is a voltage-controlled current source VDCS. According to the power semiconductor device 102, the following effects can be obtained.

The sense current I_{T101-3} is equal to the collector-emitter current I_{Q2} at the second transistor Q₂.

When (sense current I_{T101-3})<(collector-emitter current I_{Q1} at first transistor Q₁), a base current is excessively supplied to the second transistor Q₂, and the collector-emitter voltage V_{Q2} at the second transistor Q₂ is kept lower than the collector-emitter voltage V_{Q1} at the first transistor Q₁. That is, the voltage V_{GS} between the gate terminal T₁₀₁₋₄ and the sense terminal T₁₀₁₋₃ of the power semiconductor element Q₁₀₁ is not greatly different from the voltage V_{GE} between the gate terminal T₁₀₁₋₄ and the emitter terminal T₁₀₁₋₂, which allows V_{GS}≈V_{GE} to hold. Therefore, the proportional relationship between the emitter current I_{T101-2} and the sense current I_{T101-3} at the power semiconductor element Q₁₀₁ is maintained with high accuracy.

When (sense current I_{T101-3})>(collector-emitter current I_{Q1} at first transistor Q₁), the second transistor Q₂ cannot sink current, and thus the collector-emitter voltage V_{Q2} at the second transistor Q₂ becomes a high value. That is, when the sense current I_{T101-3} exceeds the collector-emitter current I_{Q1} at the first transistor Q₁, a potential V₁₀₁₋₃ of the sense terminal T₁₀₁₋₃ greatly changes. Therefore, by detecting the potential of the sense terminal T₁₀₁₋₃, it is possible to clearly determine overcurrent or short-circuit current and easily create a circuit for protecting the power semiconductor element Q₁₀₁ and the power semiconductor device 102.

### D. Third Preferred Embodiment

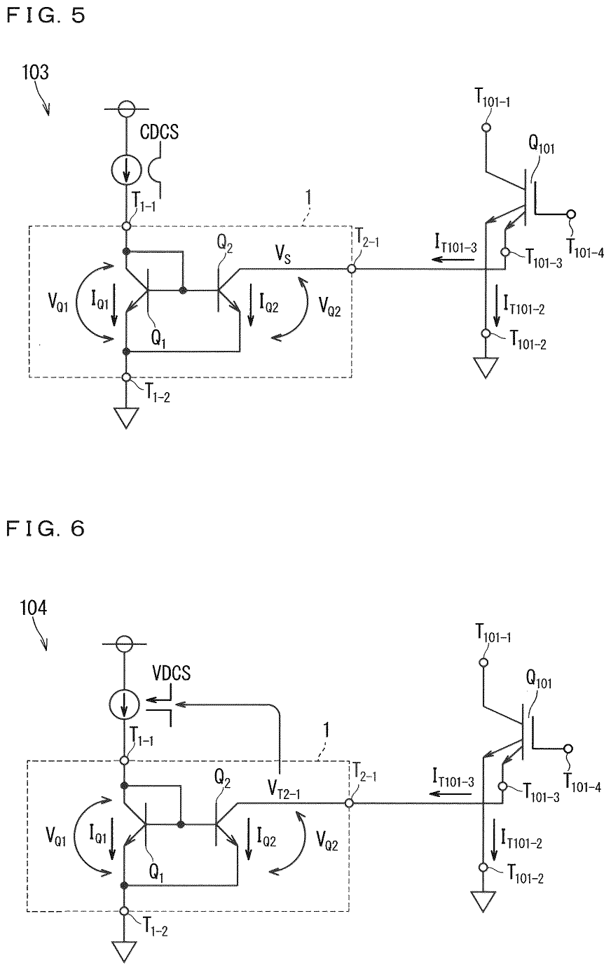

FIG. 5 is a circuit diagram of a power semiconductor device 103 of a third preferred embodiment. The power semiconductor device 103 is different from the power semiconductor device 101 of the first preferred embodiment only in that the first current source CS that supplies a current to the input terminal T₁₋₁ of the first current mirror circuit 1 is a current-controlled current source CDCS. According to the power semiconductor device 103, the following effects can be obtained.

The sense current I_{T101-3} is equal to the collector-emitter current I_{Q2} at the second transistor Q₂.

When (sense current I_{T101-3})<(collector-emitter current I_{Q1} at first transistor Q₁), a base current is excessively supplied to the second transistor Q₂, and the collector-emitter voltage V_{Q2} at the second transistor Q₂ is kept lower than the collector-emitter voltage V_{Q1} at the first transistor Q₁. That is, the voltage V_{GS} between the gate terminal T₁₀₁₋₄ and the sense terminal T₁₀₁₋₃ of the power semiconductor element Q₁₀₁ is not greatly different from the voltage V_{GE} between the gate terminal T₁₀₁₋₄ and the emitter terminal T₁₀₁₋₂, which allows V_{GS}≈V_{GE} to hold. Therefore, the proportional relationship between the emitter current I_{T101-2} and the sense current I_{T101-3} at the power semiconductor element Q₁₀₁ is maintained with high accuracy.

When (sense current I_{T101-3})>(collector-emitter current I_{Q1} at first transistor Q₁), the second transistor Q₂ cannot sink current, and thus the collector-emitter voltage V_{Q2} at the second transistor Q₂ becomes a high value. That is, when the sense current I_{T101-3} exceeds the collector-emitter current I_{Q1} at the first transistor Q₁, a potential V₁₀₁₋₃ of the sense terminal T₁₀₁₋₃ greatly changes. Therefore, by detecting the potential of the sense terminal T₁₀₁₋₃, it is possible to clearly determine overcurrent or short-circuit current and easily create a circuit for protecting the power semiconductor element Q₁₀₁ and the power semiconductor device 103.

### E. Fourth Preferred Embodiment

FIG. 6 is a circuit diagram of a power semiconductor device 104 of a fourth preferred embodiment. The power semiconductor device 104 is different from the power semiconductor device 102 of the second preferred embodiment only in that the voltage-controlled current source VDCS that supplies a current to the input terminal T₁₋₁ of the first current mirror circuit 1 is controlled by a sense voltage V_{T2-1} that is the voltage of the output terminal T₂₋₁ of the first current mirror circuit 1. According to the power semiconductor device 104, the following effects can be obtained.

In the power semiconductor device 104, the voltage-controlled current source VDCS that supplies a current to the input terminal T₁₋₁ of the first current mirror circuit 1 is controlled by the sense voltage V_{T2-1}, and thus the sense voltage V_{T2-1} becomes constant without being changed by the sense current I_{T101-3}. As a result, the current division ratio between the emitter current I_{T101-2}, which is the main current at the power semiconductor element Q₁₀₁, and the sense current I_{T101-3} is stabilized without being changed by the emitter current I_{T101-2}. Since the current division ratio is stabilized, the emitter current I_{T101-2} can be estimated from the sense current I_{T101-3} with high accuracy.

### F. Fifth Preferred Embodiment

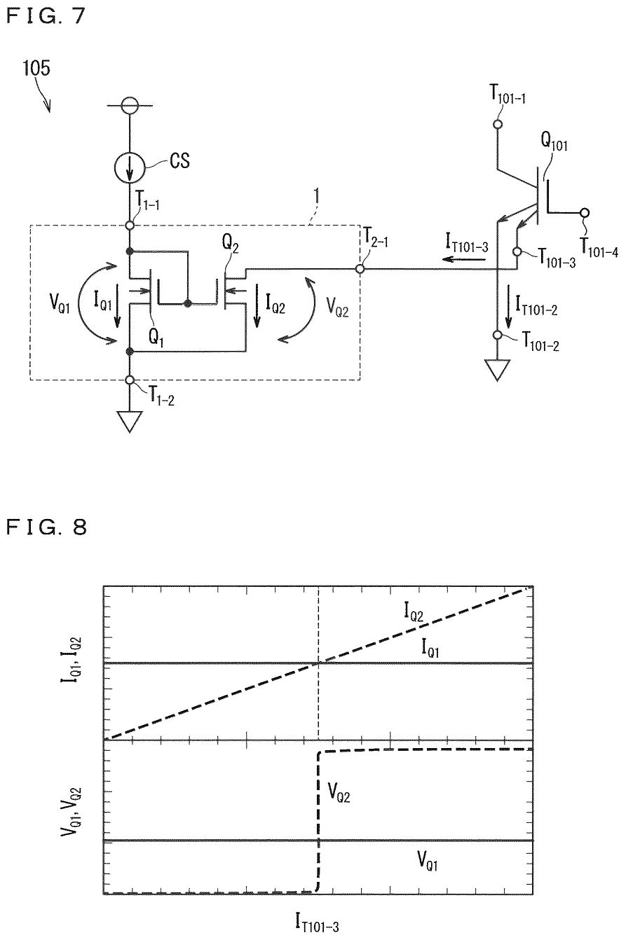

FIG. 7 is a circuit diagram of a power semiconductor device 105 of a fifth preferred embodiment. The power semiconductor device 105 is different from the power semiconductor device 101 of the first preferred embodiment in that both the first transistor Q₁ and the second transistor Q₂ of the first current mirror circuit 1 are metal oxide semiconductor field effect transistors (MOSFETs).

The voltage and current at each part of the power semiconductor device 105 are as illustrated in FIG. 8.

According to the configuration of the power semiconductor device 105, the potential difference between the emitter terminal T₁₀₁₋₂ and the sense terminal T₁₀₁₋₃ of the power semiconductor element Q₁₀₁ is as small as possible and becomes a constant value, so that the current division ratio between the emitter current I_{T101-2} and the sense current I_{T101-3} is stabilized. As a result, the emitter current I_{T101-2} can be estimated from the sense current I_{T101-3} with high accuracy.

### G. Sixth Preferred Embodiment

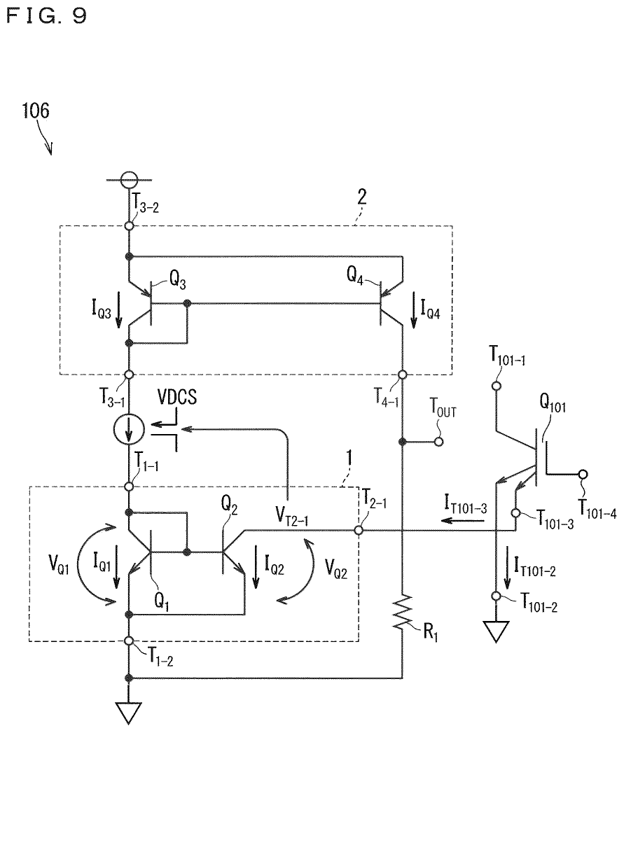

FIG. 9 is a circuit diagram of a power semiconductor device 106 of a sixth preferred embodiment.

The power semiconductor device 106 is obtained by adding a second current mirror circuit 2 to the power semiconductor device 104 of the fourth preferred embodiment. The second current mirror circuit 2 includes a third transistor Q₃ and a fourth transistor Q₄. In the example of FIG. 9, both the third transistor Q₃ and the fourth transistor Q₄ are bipolar transistors. The third transistor Q₃ is a reference transistor, while the fourth transistor Q₄ is a mirror transistor.

An emitter terminal T₃₋₁, which is the main terminal of the third transistor Q₃, is connected to the negative terminal of the voltage-controlled current source VDCS. An emitter terminal T₄₋₁, which is the main terminal of the fourth transistor Q₄, is connected to the emitter terminal T₁₋₂ of the first current mirror circuit 1 via a first resistor R₁, and is connected to an output terminal T_{OUT}.

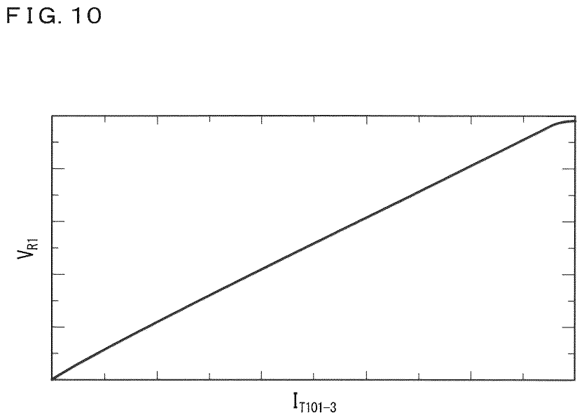

According to the above configuration, a voltage drop V_{R1} in the first resistor R₁ is proportional to the sense current I_{T101-3}, as illustrated in FIG. 10. Therefore, by reading the voltage drop V_{R1} in the first resistor R₁ at the output terminal T_{OUT}, it is possible to grasp a change in the sense current I_{T101-3}, detect an overcurrent or a short-circuit current, and protect the power semiconductor element Q₁₀₁ and the power semiconductor device 106.

### H. Seventh Preferred Embodiment

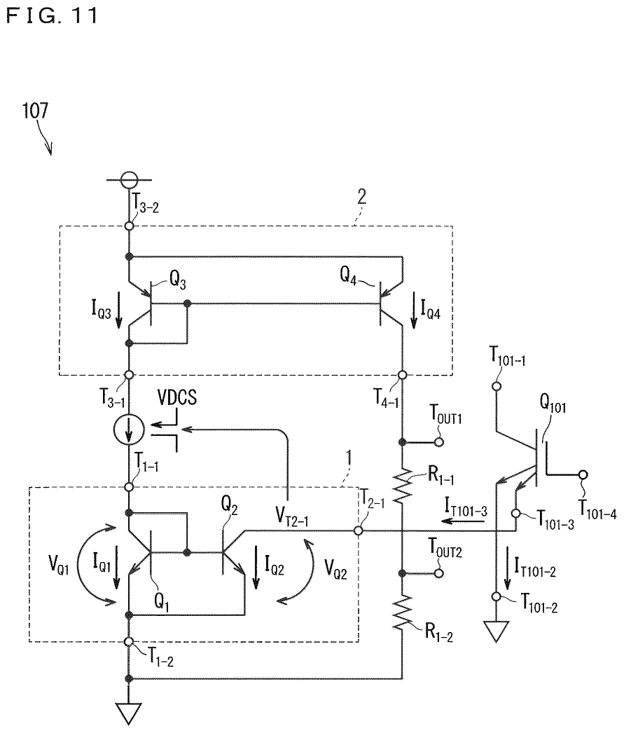

FIG. 11 is a circuit diagram of a power semiconductor device 107 of a seventh preferred embodiment.

The power semiconductor device 107 is different from the power semiconductor device 106 of the sixth preferred embodiment only in that a plurality of first resistors, connected in series, are connected between the emitter terminal T₄₋₁ of the fourth transistor Q₄ of the second current mirror circuit 2 and the emitter terminal T₁₋₂ of the first current mirror circuit 1.

In the example of FIG. 11, a first resistor R₁₋₁ and a first resistor R₁₋₂ are connected between the emitter terminal T₄₋₁ and the emitter terminal T₁₋₂. A first output terminal T_{OUT1} is connected between the emitter terminal T₄₋₁ and the first resistor R₁₋₁, and a second output terminal T_{OUT2} is connected between the first resistor R₁₋₁ and the first resistor R₁₋₂.

According to the above configuration, the sense current I_{T101-3} can be read as a plurality of voltage values, so that a plurality of thresholds for overcurrent or short-circuit current protection can be set.

### I. Eighth Preferred Embodiment

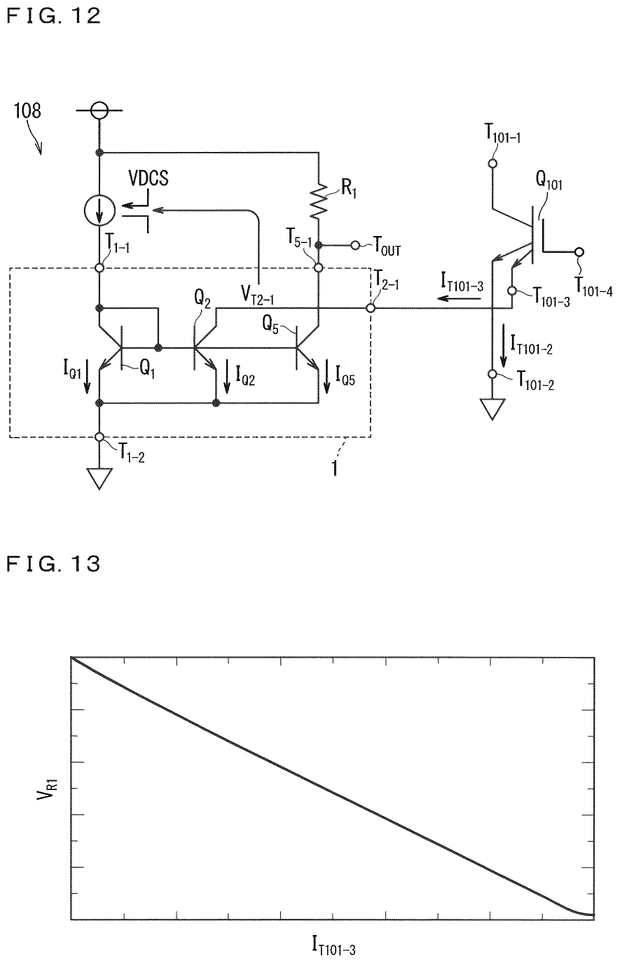

FIG. 12 is a circuit diagram of a power semiconductor device 108 of an eighth preferred embodiment.

In the power semiconductor device 108, the first current mirror circuit 1 includes a fifth transistor Q₅ in addition to the first transistor Q₁ and the second transistor Q₂. In the example of FIG. 12, the fifth transistor Q₅ is a bipolar transistor. A base terminal, which is the control terminal of the fifth transistor Q₅, is connected to the base terminals of the first transistor Q₁ and the second transistor Q₂. In addition, a first resistor R₁ is connected between a collector terminal T₅₋₁, which is the output terminal of the fifth transistor Q₅, and the negative terminal of the voltage-controlled current source VDCS. Furthermore, the output terminal T_{OUT} is provided between the first resistor R₁ and the collector terminal T₅₋₁. The power semiconductor device 108 is different from the power semiconductor device 104 of the fourth preferred embodiment only in the above points.

FIG. 13 illustrates a relationship between the voltage drop V_{R1} across the first resistor R₁ measured at the output terminal T_{OUT} and the sense current I_{T101-3}. As illustrated in FIG. 13, the voltage drop V_{R1} is proportional to the sense current I_{T101-3}. Therefore, by reading the voltage drop V_{R1} at the output terminal T_{OUT}, it is possible to grasp a change in the sense current I_{T101-3}, detect an overcurrent or a short-circuit current, and protect the power semiconductor element Q₁₀₁ and the power semiconductor device 108.

### J. Ninth Preferred Embodiment

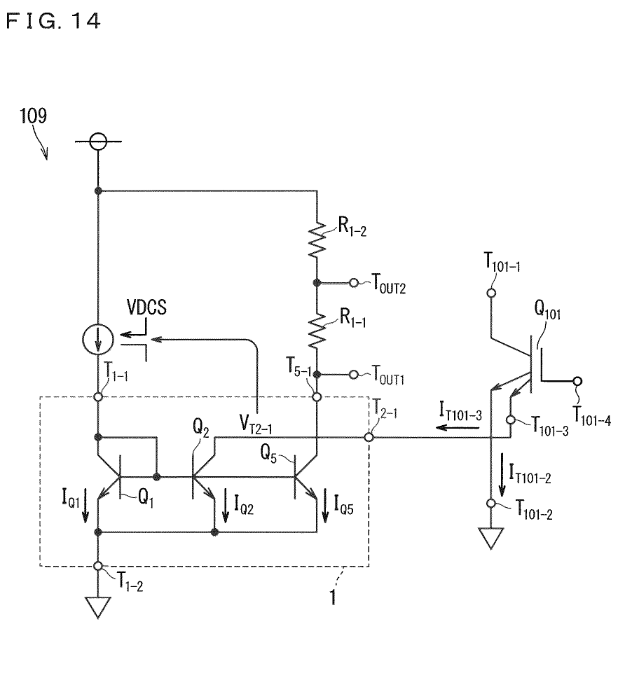

FIG. 14 is a circuit diagram of a power semiconductor device 109 of a ninth preferred embodiment.

The power semiconductor device 109 is different from the power semiconductor device 108 of the eighth preferred embodiment only in that a plurality of resistors, connected in series, are connected between the collector terminal T₅₋₁ of the fifth transistor Q₅ and the negative terminal of the voltage-controlled current source VDCS.

In the example of FIG. 14, a first resistor R₁₋₁ and a first resistor R₁₋₂ are connected between the collector terminal T₅₋₁ and the negative terminal of the voltage-controlled current source VDCS. A first output terminal T_{OUT1} is connected between the collector terminal T₅₋₁ and the first resistor R₁₋₁, and a second output terminal T_{OUT2} is connected between the first resistor R₁₋₁ and the first resistor R₁₋₂.

According to the above configuration, the sense current I_{T101-3} can be read as a plurality of voltage values, so that a plurality of thresholds for overcurrent or short-circuit current protection can be set.

### K. Tenth Preferred Embodiment

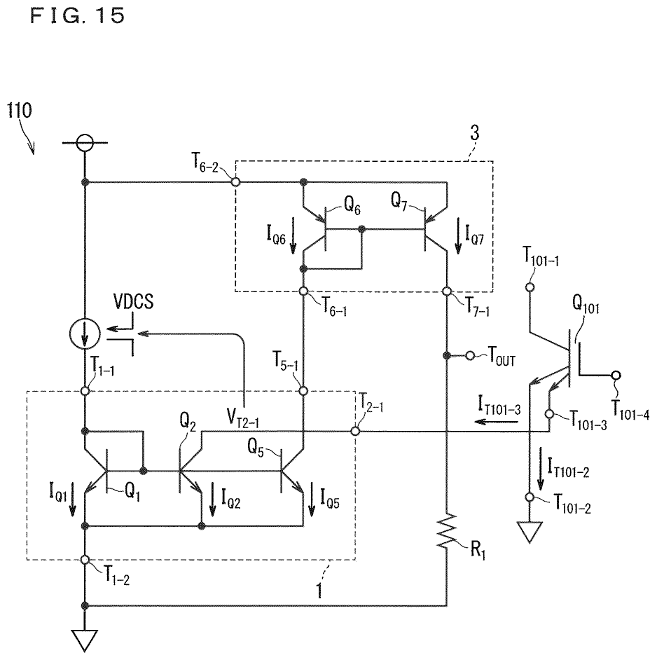

FIG. 15 is a circuit diagram of a power semiconductor device 110 of a tenth preferred embodiment.

The power semiconductor device 110 includes a third current mirror circuit 3 in addition to the configuration of the power semiconductor device 108 of the eighth preferred embodiment, and a first resistor R₁ is connected to the third current mirror circuit 3.

The third current mirror circuit 3 includes a sixth transistor Q₆ and a seventh transistor Q₇. In the example of FIG. 15, both the sixth transistor Q₆ and the seventh transistor Q₇ are bipolar transistors. Collector terminals, which are the output terminals of the sixth transistor Q₆ and the seventh transistor Q₇, are connected to the negative terminal of the voltage-controlled current source VDCS. Base terminals, which are the control terminals of the sixth transistor Q₆ and the seventh transistor Q₇, are connected to each other. An emitter terminal T₆₋₁, which is the main terminal of the sixth transistor Q₆, is connected to the collector terminal T₅₋₁ of the first current mirror circuit 1.

An emitter terminal T₇₋₁, which is the main terminal of the seventh transistor Q₇, is connected to the emitter terminal T₁₋₂ of the first current mirror circuit 1 via the first resistor R₁, and is connected to the output terminal T_{OUT}.

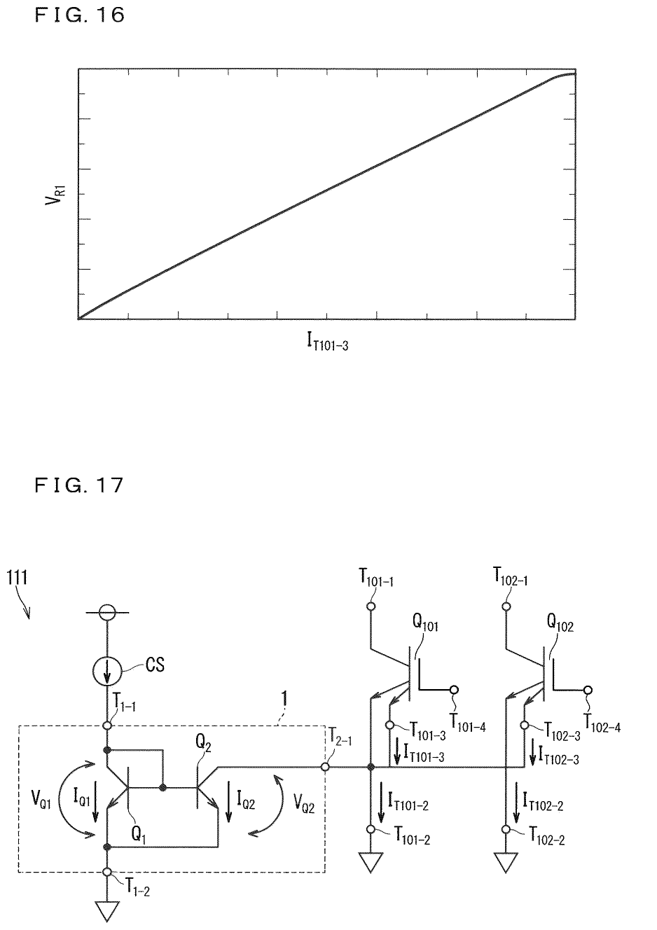

FIG. 16 illustrates a relationship between the voltage drop V_{R1} across the first resistor R₁ measured at the output terminal T_{OUT} and the sense current I_{T101-3}. As illustrated in FIG. 16, the voltage drop V_{R1} is proportional to the sense current I_{T101-3}. Therefore, by reading the voltage drop V_{R1} at the output terminal T_{OUT}, it is possible to grasp a change in the sense current I_{T101-3}, detect an overcurrent or a short-circuit current, and protect the power semiconductor element Q₁₀₁ and the power semiconductor device 110.

### L. Eleventh Preferred Embodiment

FIG. 17 is a circuit diagram of a power semiconductor device 111 of an eleventh preferred embodiment.

The power semiconductor device 111 includes at least one power semiconductor element in addition to the configuration of the power semiconductor device 101 of the first preferred embodiment. In the example of FIG. 17, the power semiconductor device 111 includes a power semiconductor element Q₁₀₂ in addition to the power semiconductor element Q₁₀₁. A sense terminal T₁₀₂₋₃ of the power semiconductor element Q₁₀₂ is connected to the sense terminal T₁₀₁₋₃ of the power semiconductor element Q₁₀₁.

In the example of FIG. 17, the power semiconductor device 111 includes one power semiconductor element Q₁₀₂ in addition to the power semiconductor element Q₁₀₁, but may include a plurality of power semiconductor elements in addition to the power semiconductor element Q₁₀₁. In this case, the sense terminal of each of the plurality of power semiconductor elements is connected to the sense terminal T₁₀₁₋₃ of the power semiconductor element Q₁₀₁.

According to the power semiconductor device 111, the sum of the sense currents I_{T101-3}, I_{T101-2} at the plurality of power semiconductor elements Q₁₀₁, Q₁₀₂ becomes the collector-emitter current I_{Q2} at the second transistor Q₂ of the first current mirror circuit 1. Therefore, by monitoring a change in the sense voltage V_{T2-1}, which is the voltage of the output terminal T₂₋₁ of the first current mirror circuit 1, it is possible to determine whether the sum of the sense currents I_{T101-3}, I_{T101-2} at the plurality of power semiconductor elements Q₁₀₁, Q₁₀₂ exceeds I_{Q1}. That is, an overcurrent can be detected from the sum of the sense currents I_{T101-3}, I_{T101-2} at the plurality of power semiconductor elements Q₁₀₁, Q₁₀₂, and the plurality of power semiconductor elements Q₁₀₁, Q₁₀₂ and the power semiconductor device 111 can be protected. Therefore, the number of circuits required to read the currents at the plurality of power semiconductor elements Q₁₀₁, Q₁₀₂ can be reduced.

### M. Twelfth Preferred Embodiment

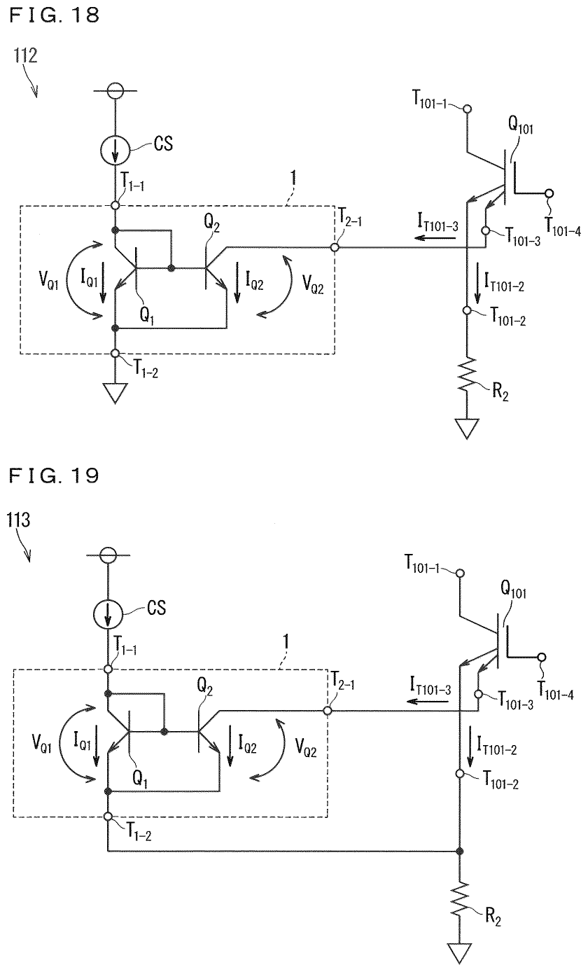

FIG. 18 is a circuit diagram of a power semiconductor device 112 of a twelfth preferred embodiment.

The power semiconductor device 112 is different from the power semiconductor device 101 of the first preferred embodiment only in that a second resistor R₂ is connected to the emitter terminal T₁₀₁₋₂ of the power semiconductor element Q₁₀₁.

According to the configuration of the power semiconductor device 112 described above, the potential difference between the emitter terminal T₁₀₁₋₂ and the sense terminal T₁₀₁₋₃ of the power semiconductor element Q₁₀₁ is made as small as possible and constant, so that the current division ratio between the emitter current I_{T101-2} and the sense current I_{T101-3} can be stabilized. As a result, the emitter current I_{T101-2} can be estimated from the sense current I_{T101-3} with high accuracy.

### N. Thirteenth Preferred Embodiment

FIG. 19 is a circuit diagram of a power semiconductor device 113 of a thirteenth preferred embodiment.

The power semiconductor device 113 is different from the power semiconductor device 112 of the twelfth preferred embodiment only in that the main terminal T₁₋₂ of the first current mirror circuit 1 is connected to the emitter terminal T₁₀₁₋₂ of the power semiconductor element Q₁₀₁.

According to the configuration of the power semiconductor device 113 described above, the potential difference between the emitter terminal T₁₀₁₋₂ and the sense terminal T₁₀₁₋₃ of the power semiconductor element Q₁₀₁ is made as small as possible and constant, so that the current division ratio between the emitter current I_{T101-2} and the sense current I_{T101-3} can be stabilized. As a result, the emitter current I_{T101-2} can be estimated from the sense current I_{T101-3} with high accuracy.

### O. Fourteenth Preferred Embodiment

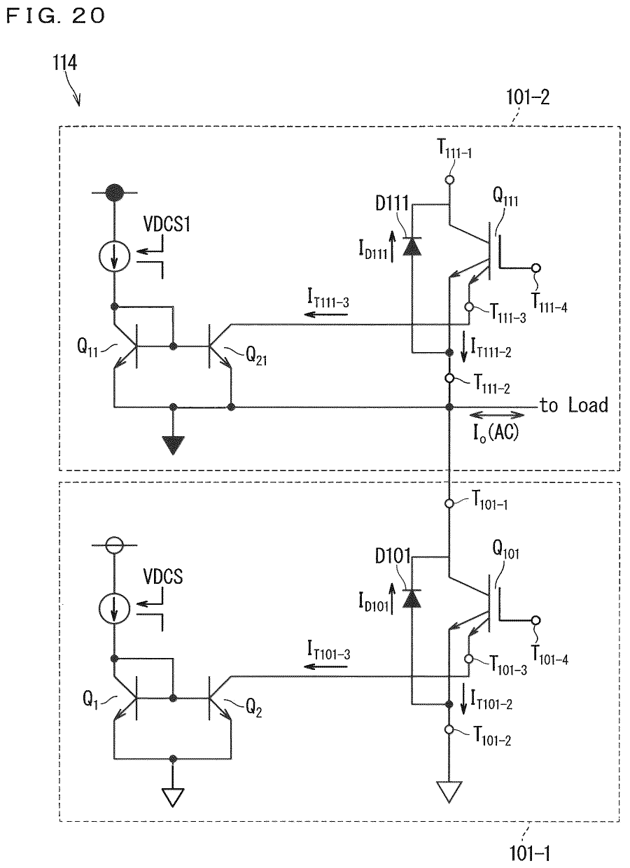

FIG. 20 is a circuit diagram of a power semiconductor device 114 of a fourteenth preferred embodiment.

The power semiconductor device 114 has a configuration in which a power semiconductor device 101-1 and a power semiconductor device 101-2 are connected in series. Each of the power semiconductor devices 101-1,101-2 corresponds to the power semiconductor device 101 of the first preferred embodiment.

In FIG. 20, the configurations of the respective parts of the power semiconductor device 101-1 are denoted by the same reference numerals as those of the power semiconductor device 101. In addition, the configurations of the power semiconductor device 101-2, corresponding to the first transistor Q₁, the second transistor Q₂, the power semiconductor element Q₁₀₁, the emitter terminal T₁₀₁₋₂, the sense terminal T₁₀₁₋₃, and the gate terminal T₁₀₁₋₄ of the power semiconductor device 101-1, are denoted by reference numerals Q₁₁, Q₂₁, Q₁₁₁, T₁₁₁₋₂, T₁₁₁₋₃, and T₁₁₁₋₄. Note that FIG. 20 illustrates body diodes D₁₀₁, D₁₁₁ of the power semiconductor elements Q₁₀₁, Q₁₁₁.

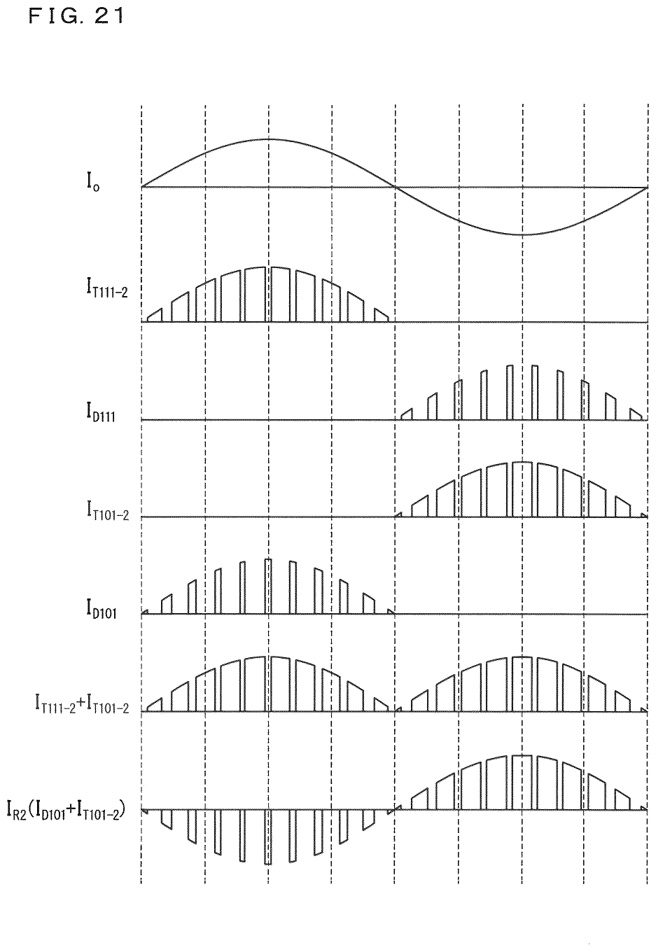

FIG. 21 illustrates a current waveform at each part of the power semiconductor device 114. A load current Io, an emitter current I_{T111-2} at the power semiconductor element Q₁₁₁, a current I_{D111} flowing through the body diode D₁₁₁, an emitter current I_{T101-2} at the power semiconductor element Q₁₀₁, a current I_{D101} flowing through the body diode D₁₀₁, and the sum (I_{T111-2}+I_{T101-2}) of the emitter currents of the power semiconductor elements Q₁₁₁, Q₁₀₁ are illustrated.

In the example of FIG. 20, the power semiconductor devices 101-1,101-2 are connected in series, but they may be connected in parallel.

According to the configuration of the power semiconductor device 114 described above, it is capable of reproducing the output current at a half-bridge circuit and reproducing the load current over the entire AC range.

### P. Fifteenth Preferred Embodiment

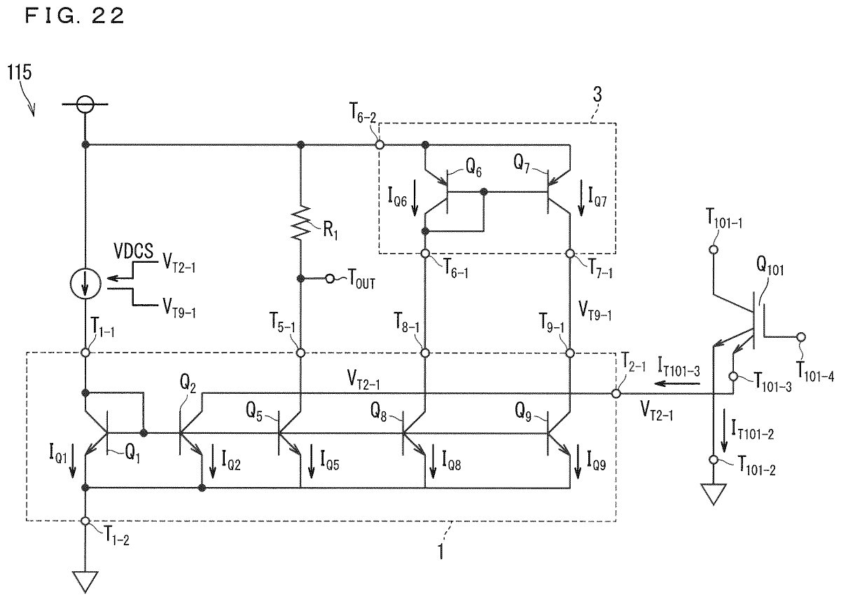

FIG. 22 is a circuit diagram of a power semiconductor device 115 of a fifteenth preferred embodiment.

The power semiconductor device 115 is different from the power semiconductor device 110 of the tenth preferred embodiment in the following points. The first current mirror circuit 1 includes an eighth transistor Q₈ and a ninth transistor Q₉. In the example of FIG. 22, both the eighth transistor Q₈ and the ninth transistor Q₉ are bipolar transistors. The third current mirror circuit 3 is connected to collector terminals T₈₋₁, T₉₋₁ that are the output terminals of the eighth transistor Q₈ and the ninth transistor Q₉. A first resistor R₁ is connected between the collector terminal T₅₋₁ of the fifth transistor Q₅ and the negative terminal of the voltage-controlled current source VDCS, and an output terminal T_{OUT} is provided between the first resistor R₁ and the collector terminal T₅₋₁. The power semiconductor device 115 is different from the power semiconductor device 110 of the tenth preferred embodiment only in the above points.

Base terminals of the eighth transistor Q₈ and the ninth transistor Q₉ are connected to the base terminals of the first transistor Q₁ and the second transistor Q₂.

The emitter terminal T₆₋₁ of the sixth transistor Q₆ of the third current mirror circuit 3 is connected to a collector terminal T₈₋₁ of the eighth transistor Q₈ of the first current mirror circuit 1. The emitter terminal T₇₋₁ of the seventh transistor Q₇ of the third current mirror circuit 3 is connected to a collector terminal T₉₋₁ of the ninth transistor Q₉ of the first current mirror circuit 1.

The sense terminal T₁₀₁₋₃ of the power semiconductor element Q₁₀₁ is connected to the collector of the second transistor Q₂ of the first current mirror circuit 1. Although the collector potential of the second transistor Q₂ is set to be low, the collector potential does not become 0 V and a remaining voltage occurs.

The control voltage of the voltage-controlled current source VDCS is not a voltage between the sense voltage V_{T2-1}, which is the voltage of the sense terminal T₁₀₁₋₃, and GND, but is a voltage between the sense voltage V_{T2-1} and a collector voltage V_{T9-1} of the ninth transistor Q₉.

In the steady state, the emitter current I_{Q2} at the second transistor Q₂ is equal to the emitter current I_{Q9} at the ninth transistor Q₉, and thus the potential difference between the sense voltage V_{T2-1} and the collector voltage V_{T9-1} of the ninth transistor Q₉ is 0 V.

When the emitter current I_{Q2} at the second transistor Q₂ becomes not equal to the emitter current I_{Q9} at the ninth transistor Q₉, a potential difference occurs between the sense voltage V_{T2-1} and the collector voltage V_{T9-1} of the ninth transistor Q₉. As a result, the controlled-voltage of the voltage-controlled current source VDCS varies with reference to 0 V.

A current mirror circuit including the sixth transistor Q₆ and the seventh transistor Q₇ is formed in a parallel circuit in which bases and emitters of the second transistor Q₂, the eighth transistor Q₈, and the ninth transistor Q₉ are connected; conduction currents at the second transistor Q₂ and the ninth transistor Q₉ are balanced in a steady state; and I_{Q2}=I_{Q9} is satisfied, whereby temperature dependency of a transistor forming the current mirror circuit can be canceled. Therefore, the current reading accuracy in a sense current reading circuit including the current mirror circuit and the voltage-controlled current source VDCS can be improved.

### Q. Sixteenth Preferred Embodiment

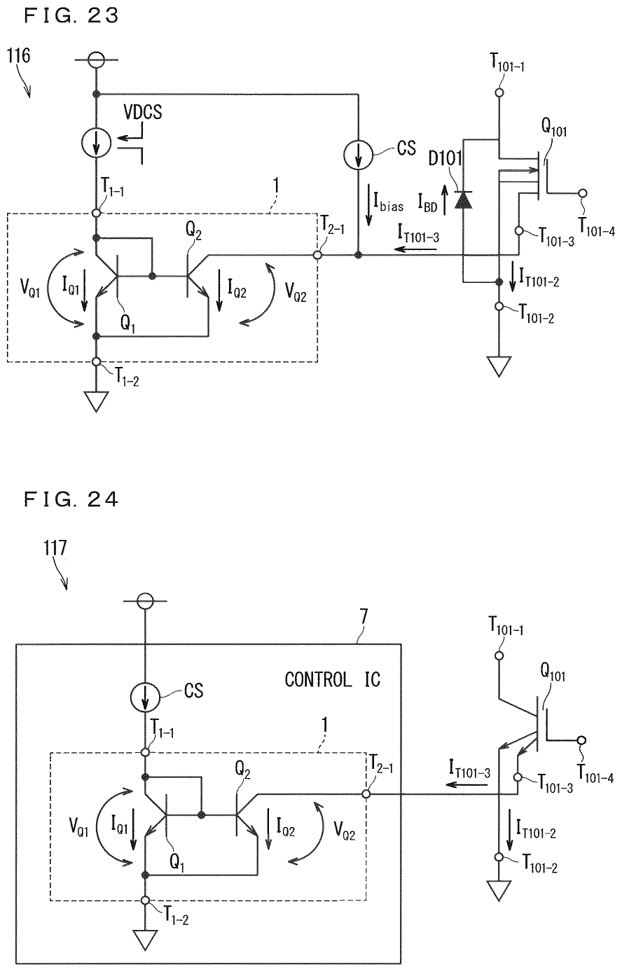

FIG. 23 is a circuit diagram of a power semiconductor device 116 of a sixteenth preferred embodiment.

The power semiconductor device 116 is obtained by using, in the power semiconductor device 104 of the fourth preferred embodiment illustrated in FIG. 6, a MOSFET as the power semiconductor element Q₁₀₁ and connecting a second current source CS between the sense terminal T₁₀₁₋₃ and the positive terminal of the voltage-controlled current source VDCS.

By causing a bias current Ibias to flow from the second current source CS, the forward current and reverse current of the sense current I_{T101-3} can be read from the sense voltage V_{T2-1}.

By applying a potential to the gate of the power semiconductor element Q₁₀₁ to turn on the channel of the MOSFET, the forward currents and reverse currents of the source current I_{T101-2} and the sense current I_{T101-3} can be read. Since the reverse currents can also be read, an alternating current can be read by only one arm, that is, by only the upper arm or only the lower arm.

In a MOSFET, a parasitic element, which will be connected in anti-parallel to a channel of the MOSFET called a body diode, is generally generated. In FIG. 23, this body diode is denoted as D₁₀₁. In order to correctly read the reverse current, the magnitude of the reverse current needs to be in a range in which the body diode D₁₀₁ is not operated. Therefore, the present preferred embodiment is particularly useful when the power semiconductor element Q₁₀₁ is a power semiconductor element using a wide bandgap semiconductor, such as SiC or GaN, in which the forward voltage drop across the body diode D₁₀₁ is large.

### R. Seventeenth Preferred Embodiment

FIG. 24 is a circuit diagram of a power semiconductor device 117 of a seventeenth preferred embodiment. The power semiconductor device 117 is different from the power semiconductor device 101 of the first preferred embodiment in that the first current mirror circuit 1 and the first current source CS are mounted inside a control integrated circuit (IC) 7.

By making the potential difference between the emitter terminal T₁₀₁₋₂ and the sense terminal T₁₀₁₋₃ of the power semiconductor element Q₁₀₁ as small as possible and constant, the current division ratio between the emitter current I_{T101-2} and the sense current I_{T101-3} can be stabilized. As a result, the emitter current I_{T101-2} can be estimated from the sense current I_{T101-3} with high accuracy.

Although the preferred embodiments and the like have been described in detail above, various modifications and substitutions can be made to the above-described preferred embodiments and the like without being limited to the above-described preferred embodiments and the like and departing from the scope described in the claims.

Hereinafter, various aspects of the present disclosure will be collectively described as Appendices.

### Appendix 1

A power semiconductor device comprising:
at least one power semiconductor element having a main terminal through which a main current flows and a sense terminal through which a sense current proportional to the main current flows; and
a first current mirror circuit, wherein
the sense terminal is connected to an output terminal of the first current mirror circuit, and
an input terminal of the first current mirror circuit is connected to a first current source.

### Appendix 2

The power semiconductor device according to Appendix 1, wherein
the first current mirror circuit has a first transistor and a second transistor,
an output terminal of the first transistor, a control terminal of the first transistor, and a control terminal of the second transistor are connected to the first current source, and
an output terminal of the second transistor is connected to the sense terminal as an output terminal of the first current mirror circuit.

### Appendix 3

The power semiconductor device according to Appendix 2, wherein the first current source is a constant current source.

### Appendix 4

The power semiconductor device according to Appendix 2, wherein the first current source is a voltage-controlled current source.

### Appendix 5

The power semiconductor device according to Appendix 2, wherein the first current source is a current-controlled current source.

### Appendix 6

The power semiconductor device according to Appendix 4, wherein the voltage-controlled current source is controlled by a sense voltage that is a voltage at the sense terminal.

### Appendix 7

The power semiconductor device according to Appendix 6, wherein the first transistor and the second transistor are bipolar transistors or MOSFETs.

### Appendix 8

The power semiconductor device according to Appendix 6, comprising:
a second current mirror circuit having a third transistor and a fourth transistor; and
at least one first resistor connected to a main terminal of the fourth transistor, wherein
a main terminal of the third transistor is connected to the voltage-controlled current source.

### Appendix 9

The power semiconductor device according to Appendix 8, wherein the at least one first resistor includes a plurality of first resistors connected in series.

### Appendix 10

The power semiconductor device according to Appendix 6, wherein
the first current mirror circuit has a fifth transistor,
a control terminal of the fifth transistor is connected to the control terminal of the first transistor and the control terminal of the second transistor, and
at least one first resistor to be connected to an output terminal of the fifth transistor is included.

### Appendix 11

The power semiconductor device according to Appendix 10, wherein the at least one first resistor includes a plurality of first resistors connected in series.

### Appendix 12

The power semiconductor device according to Appendix 6, wherein
the first current mirror circuit has a fifth transistor, and
a control terminal of the fifth transistor is connected to the control terminal of the first transistor and the control terminal of the second transistor,
the power semiconductor device comprising:
a third current mirror circuit having a sixth transistor and a seventh transistor; and
a first resistor to be connected to a main terminal of the seventh transistor, wherein
a main terminal of the sixth transistor is connected to an output terminal of the fifth transistor.

### Appendix 13

The power semiconductor device according to any one of Appendices 1 to 12, wherein
the at least one power semiconductor element includes a plurality of power semiconductor elements, and
the sense terminals of the plurality of power semiconductor elements are connected to each other.

### Appendix 14

The power semiconductor device according to any one of Appendices 1 to 13, wherein a second resistor is connected to a main terminal of the at least one power semiconductor element.

### Appendix 15

The power semiconductor device according to Appendix 14, wherein a main terminal of the first transistor of the first current mirror circuit is connected to the main terminal of the power semiconductor element.

### Appendix 16

A power semiconductor device comprising a plurality of the power semiconductor devices according to any one of Appendices 1 to 15 that are connected in series.

### Appendix 17

A power semiconductor device comprising a plurality of the power semiconductor devices according to any one of Appendices 1 to 15 that are connected in parallel.

### Appendix 18

The power semiconductor device according to Appendix 6, wherein
the first current mirror circuit includes a fifth transistor, an eighth transistor, and a ninth transistor, and
a control terminal of the fifth transistor, a control terminal of the eighth transistor, and a control terminal of the ninth transistor are connected to the control terminal of the first transistor and the control terminal of the second transistor,
the power semiconductor device comprising:
a third current mirror circuit having a sixth transistor and a seventh transistor; and
a first resistor to be connected to an output terminal of the fifth transistor, wherein
an output terminal of the sixth transistor and a control terminal of the seventh transistor are connected to the first current source,
a main terminal of the sixth transistor is connected to an output terminal of the eighth transistor, and
a main terminal of the seventh transistor is connected to an output terminal of the ninth transistor.

### Appendix 19

The power semiconductor device according to Appendix 6, wherein
the power semiconductor element is a MOSFET, and
a second current source to be connected to the sense terminal is included.

### Appendix 20

The power semiconductor device according to any one of Appendices 1 to 19, wherein the first current mirror circuit and the first current source are formed inside a control IC.

### Appendix 21

The power semiconductor device according to any one of Appendices 1 to 20, wherein a semiconductor material of the power semiconductor element contains SiC.

### Appendix 22

The power semiconductor device according to any one of Appendices 1 to 21, wherein the sense terminal is connected to an output terminal of the first current mirror circuit by a wire containing at least one material of Al, Au, and Ag.

### Appendix 23

The power semiconductor device according to any one of Appendices 1 to 22, being sealed with a sealing material.

While the disclosure has been shown and described in detail, the foregoing description is in all aspects illustrative and not restrictive. It is therefore understood that numerous modifications and variations can be devised.

What is claimed is:

1. A power semiconductor device comprising:
at least one power semiconductor element having a main terminal through which a main current flows and a sense terminal through which a sense current proportional to the main current flows; and
a first current mirror circuit, wherein
the sense terminal is connected to an output terminal of the first current mirror circuit, and
an input terminal of the first current mirror circuit is connected to a first current source.

2. The power semiconductor device according to claim 1, wherein
the first current mirror circuit has a first transistor and a second transistor,
an output terminal of the first transistor, a control terminal of the first transistor, and a control terminal of the second transistor are connected to the first current source, and
an output terminal of the second transistor is connected to the sense terminal as an output terminal of the first current mirror circuit.

3. The power semiconductor device according to claim 2, wherein the first current source is a constant current source.

4. The power semiconductor device according to claim 2, wherein the first current source is a voltage-controlled current source.

5. The power semiconductor device according to claim 2, wherein the first current source is a current-controlled current source.

6. The power semiconductor device according to claim 4, wherein the voltage-controlled current source is controlled by a sense voltage that is a voltage at the sense terminal.

7. The power semiconductor device according to claim 6, wherein the first transistor and the second transistor are bipolar transistors or MOSFETs.

8. The power semiconductor device according to claim 6, comprising:
a second current mirror circuit having a third transistor and a fourth transistor; and
at least one first resistor connected to a main terminal of the fourth transistor, wherein
a main terminal of the third transistor is connected to the voltage-controlled current source.

9. The power semiconductor device according to claim 8, wherein the at least one first resistor includes a plurality of first resistors connected in series.

10. The power semiconductor device according to claim 6, wherein
the first current mirror circuit has a fifth transistor,
a control terminal of the fifth transistor is connected to the control terminal of the first transistor and the control terminal of the second transistor, and
at least one first resistor to be connected to an output terminal of the fifth transistor is included.

11. The power semiconductor device according to claim 10, wherein the at least one first resistor includes a plurality of first resistors connected in series.

12. The power semiconductor device according to claim 6, wherein
the first current mirror circuit has a fifth transistor, and
a control terminal of the fifth transistor is connected to the control terminal of the first transistor and the control terminal of the second transistor,
the power semiconductor device comprising:
a third current mirror circuit having a sixth transistor and a seventh transistor; and
a first resistor to be connected to a main terminal of the seventh transistor, wherein
a main terminal of the sixth transistor is connected to an output terminal of the fifth transistor.

13. The power semiconductor device according to claim 1, wherein
the at least one power semiconductor element includes a plurality of power semiconductor elements, and
the sense terminals of the plurality of power semiconductor elements are connected to each other.

14. The power semiconductor device according to claim 2, wherein a second resistor is connected to a main terminal of the at least one power semiconductor element.

15. The power semiconductor device according to claim 14, wherein a main terminal of the first transistor of the first current mirror circuit is connected to the main terminal of the power semiconductor element.

16. A power semiconductor device comprising a plurality of the power semiconductor devices according to claim 1 that are connected in series.

17. A power semiconductor device comprising a plurality of the power semiconductor devices according to claim 1 that are connected in parallel.

18. The power semiconductor device according to claim 6, wherein
the first current mirror circuit includes a fifth transistor, an eighth transistor, and a ninth transistor, and
a control terminal of the fifth transistor, a control terminal of the eighth transistor, and a control terminal of the ninth transistor are connected to the control terminal of the first transistor and the control terminal of the second transistor,
the power semiconductor device comprising:
a third current mirror circuit having a sixth transistor and a seventh transistor; and
a first resistor to be connected to an output terminal of the fifth transistor, wherein an output terminal of the sixth transistor and a control terminal of the seventh transistor are connected to the first current source,
a main terminal of the sixth transistor is connected to an output terminal of the eighth transistor, and
a main terminal of the seventh transistor is connected to an output terminal of the ninth transistor.

19. The power semiconductor device according to claim 6, wherein
the power semiconductor element is a MOSFET, and
a second current source to be connected to the sense terminal is included.

20. The power semiconductor device according to claim 1, wherein the first current mirror circuit and the first current source are formed inside a control IC.

21. The power semiconductor device according to claim 1, wherein a semiconductor material of the power semiconductor element contains SiC.

22. The power semiconductor device according to claim 1, wherein the sense terminal is connected to an output terminal of the first current mirror circuit by a wire containing at least one material of Al, Au, and Ag.

23. The power semiconductor device according to claim 1, being sealed with a sealing material.
